(19) United States
(12) Patent Application Publication
(10) Pub. No.: US 2026/0179694 A1
(43) Pub. Date: Jun. 25, 2026

(54) VOLTAGE GENERATOR, MEMORY DEVICE AND STORAGE DEVICE COMPRISING THE SAME

(71) Applicant: Samsung Electronics Co., Ltd., Suwon-si (KR)

(72) Inventors: Eunchan LEE, Suwon-si (KR); Jeil RYU, Suwon-si (KR); Wontae KIM, Suwon-si (KR); Jayang YOON, Suwon-si (KR)

(73) Assignee: Samsung Electronics Co., Ltd., Suwon-si (KR)

(21) Appl. No.: 19/331,016

(22) Filed: Sep. 17, 2025

(30) Foreign Application Priority Data
Dec. 20, 2024 (KR) 10-2024-0192391

(51) Int. Cl. G11C 16/30; G11C 5/06; G11C 16/04; G11C 16/08; G11C 16/26

(52) U.S. Cl. CPC G11C 16/30; G11C 5/063; G11C 16/0483; G11C 16/08; G11C 16/26

(57) ABSTRACT

According to at least one example embodiment, a voltage generator includes: an oscillator configured to outputting a pump clock signal of which a frequency is determined depending on a level of an external power supply voltage, a stage controller configured to, count a number of cycles of the pump clock signal, and output a stage signal based on a data value of a reference count signal and the counted number of cycles of the pump clock signal, a multi-stage charge pump circuit configured to, determine an enable time period based on the stage signal and a magnitude of the external power supply voltage, and perform a pump operation based on a control signal and the determined enable time period, and a word line voltage generator configured to output a word line voltage based on a pump voltage.

### CROSS-REFERENCE TO RELATED APPLICATIONS

This U.S. non-provisional application claims the benefit of priority to Korean Patent Application No. 10-2024-0192391 filed on Dec. 20, 2024 in the Korean Intellectual Property Office, the disclosure of which is incorporated herein by reference in its entirety.

### BACKGROUND

Some example embodiments of the inventive concepts relate to a voltage generator, a memory device including the same, and/or a storage device including the same, and/or a method of operating the voltage generator, etc.

A memory device may include a plurality of cell strings to which a plurality of memory cells are connected. In pre-charging, during a process of performing a read operation on the memory device, a portion of the cell strings may be channel boosted in a channel layer, and a reference voltage may be applied to other portions thereof. When a level of an external power supply voltage decreases, the driving capability of a word line voltage generator may decrease thereby causing an unselected word line to take a longer time to reach a target voltage level, and/or a voltage level of the unselected word line may rise up to the target voltage level or higher. In this case, a region adjacent to the unselected word line in the channel layer may be channel boosted to a higher level. Therefore, as a high voltage difference is formed in one channel layer, a hot carrier injection (HCI) phenomenon may occur, and thus problems such as loss of data stored in the memory cells or the like may occur.

### SUMMARY

An aspect of at least one example embodiment of the inventive concepts is to provide a voltage generator capable of decreasing and/or preventing loss of data stored in a memory cell by decreasing and/or minimizing a change in time at which a word line voltage generator generates a setting voltage regardless of a change in external power supply voltage, to decrease and/or suppress an additional increase in a level on which a channel layer is channel-boosted, a method of operating the voltage generator, a memory device including the voltage generator, and/or a storage device including the voltage generator, etc.

According to at least one example embodiment of the inventive concepts, a voltage generator includes an oscillator configured to outputting a pump clock signal of which a frequency is determined depending on a level of an external power supply voltage, a stage controller configured to, count a number of cycles of the pump clock signal, and output a stage signal based on a data value of a reference count signal and the counted number of cycles of the pump clock signal, a multi-stage charge pump circuit configured to, determine an enable time period based on the stage signal and a magnitude of the external power supply voltage, and perform a pump operation based on a control signal and the determined enable time period, and a word line voltage generator configured to output a word line voltage based on a pump voltage.

According to at least one example embodiment of the inventive concepts, a memory device includes a memory cell array including a plurality of cell strings, the plurality of cell strings including a plurality of memory cells and a plurality of word lines, the plurality of memory cells respectively connected between a plurality of string select lines and a plurality of ground select lines, and the plurality of word lines connected to the plurality of memory cells, a control logic circuit configured to perform at least one read operation by controlling a row voltage supplied to the plurality of string select lines, the plurality of word lines, and the plurality of ground select lines, a voltage generator configured to output a pump clock signal, the outputting of the pump clock signal including setting a frequency of the pump clock signal based on a level of an external power supply voltage, a stage controller configured to, count a number of cycles of the pump clock signal, and output a stage signal based on a data value of a reference count signal and the counted number of cycles of the pump clock signal, a multi-stage charge pump circuit configured to, determine one or more enable time periods based on the stage signal and a magnitude of the external power supply voltage, and perform a pump operation based on a control signal and the determined one or more enable time periods, and a word line voltage generator configured to output a word line voltage based on a pump voltage.

According to at least one example embodiment of the inventive concepts, a storage device includes at least one memory device including a memory cell array, the memory cell array including a plurality of cell strings, the at least one memory device configured to perform a read operation in response to a read signal, a power circuit configured to supply an external power supply voltage to the memory device using a voltage received through an interface, a voltage generator configured to output a pump clock signal, the outputting of the pump clock signal including setting a frequency of the pump clock signal based on a level of the external power supply voltage, a stage controller configured to, count a number of cycles of the pump clock signal, and output a stage signal based on a data value of a reference count signal and the counted number of cycles of the pump clock signal, a multi-stage charge pump circuit configured to, determine one or more enable time periods based on the stage signal and a magnitude of the external power supply voltage, and perform a pump operation based on a control signal and the determined one or more enable time periods, and a word line voltage generator configured to output a word line voltage based on a pump voltage.

According to at least one example embodiment of the inventive concepts, a method of operating a storage device includes receiving an external power supply voltage, determining a pump voltage interval associated with a pumping operation based on a magnitude of an external power supply voltage, generating a pump voltage using a multi-stage charge pump circuit based on the pump voltage interval, and generating a wordline voltage based on the pump voltage and a setting voltage, and performing a pre-charge operation of a target word line of the storage device based on the wordline voltage, the target word line associated with a read operation.

Some example embodiments provide that the setting the pump voltage interval further includes, determining a magnitude of a voltage level of the external power supply voltage, and determining a delay period for each stage of the multi-stage charge pump circuit based on the determined magnitude.

Some example embodiments provide that the generating the pump voltage further includes, generating a pump clock signal using an oscillator based on the external power supply voltage, generating a feedback signal based on a voltage level of the pump voltage and a voltage level of a reference voltage, and generating a control signal for the multi-stage charge pump circuit based on the pump clock signal and the feedback signal.

Some example embodiments provide that the generating the control signal further includes, setting the control signal to a high level in response to the voltage level of the pump voltage being lower than the voltage level of the reference voltage, and outputting the control signal to the multi-stage charge pump circuit, the control signal causing the multi-stage charge pump circuit to increase the voltage level of the pump voltage.

### BRIEF DESCRIPTION OF DRAWINGS

The above and other aspects, features, and advantages of one or more example embodiments of the inventive concepts will be more clearly understood from the following detailed description, taken in conjunction with the accompanying drawings, in which:

FIG. 1 is a block diagram illustrating an example memory system including a storage device according to at least one example embodiment.

FIG. 2 is a block diagram illustrating an example memory device according to at least one example embodiment.

FIG. 3 is a circuit diagram illustrating an example memory block according to at least one example embodiment.

FIG. 4 is a circuit diagram illustrating an example portion of a memory block according to at least one example embodiment.

FIGS. 5 and 6 are views illustrating an example read operation according to at least one example embodiment.

FIG. 7 is a block diagram illustrating an example voltage generator according to at least one example embodiment.

FIG. 8 is a block diagram illustrating an example pump oscillator according to at least one example embodiment.

FIGS. 9 and 10 are circuit diagrams illustrating an example bias generation circuit according to at least one example embodiment.

FIG. 11 is a view illustrating an example operation of an oscillator according to at least one example embodiment.

FIG. 12 is a block diagram illustrating an example stage controller according to at least one example embodiment.

FIGS. 13A, 13B, 13C, and 13D are views illustrating an example operation of a stage controller according to at least one example embodiment.

FIG. 14 is a block diagram illustrating an example multi-stage charge pump circuit according to at least one example embodiment.

FIGS. 15A, 15B, 16A, and 16B are views illustrating an example operation of a word line voltage generator according to at least one example embodiment.

### DETAILED DESCRIPTION

Hereinafter, some example embodiments will be described with reference to the attached drawings as follows.

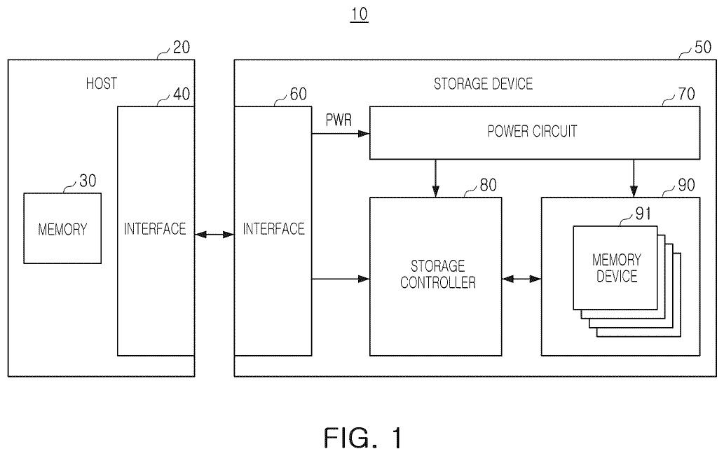

FIG. 1 is a block diagram illustrating an example memory system including a storage device according to at least one example embodiment.

Referring to FIG. 1, a system 10 according to at least one example embodiment may include at least one storage device 50 and/or at least one host 20, but the example embodiments are not limited thereto, and for example, the system 10 may include a greater or lesser number of components. The host 20 may control the storage device 50 to store data in the storage device 50 and/or to read data stored in the storage device 50, etc. The host 50 may be implemented as processing circuitry, e.g., a central processing unit (CPU), an application processor (AP), a system-on-chip (SoC), or the like, or may be an electronic device which includes such processing circuitry, but is not limited thereto.

The host 20 may include at least one interface 40 connected to the storage device 50, at least one memory 30, and the like. According to at least one example embodiment, the memory 30 may be a cache memory inside the host 20, but the example embodiments are not limited thereto.

The storage device 50 may include at least one interface 60, a power circuit 70, a storage controller 80, a memory package 90, and the like, but is not limited thereto. The storage device 50 may operate by receiving a control command from the host 20 through the interface 60, and may receive and store data in the memory package 90, and/or may extract data stored in the memory package 90 and output the data to the host 20, etc. The control command may include address information, and, with reference to the address information, the storage controller 80 may store data in at least one memory device 91 among a plurality of memory devices 91 included in the memory package 90, and/or read data from at least one among the plurality of memory devices 91, etc.

The storage device 50 may receive an external voltage PWR desired and/or required for operation from the host 20 through the interface 60. The external voltage PWR received through the interface 60 may be input to the power circuit 70, and the power circuit 70 may output a plurality of internal voltages using the external voltage PWR. The plurality of internal voltages generated by the power circuit 70 may be input to the storage controller 80 and/or the memory package 90, etc.

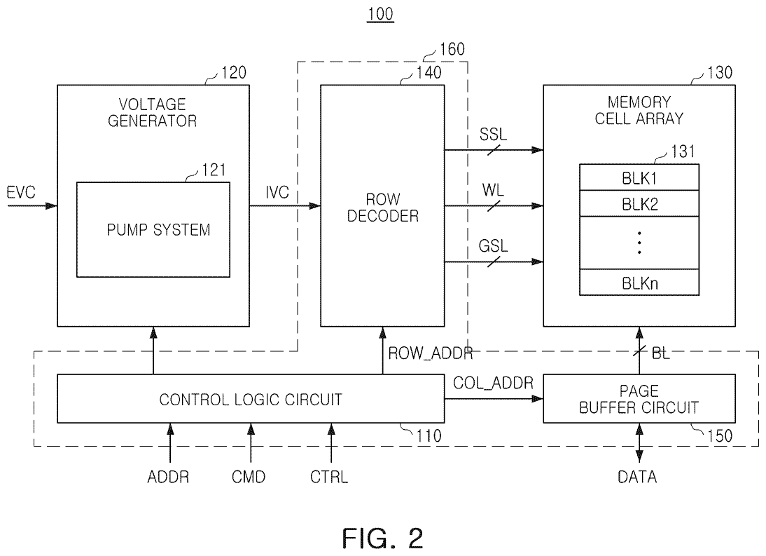

FIG. 2 is a block diagram illustrating an example memory device according to at least one example embodiment.

Referring to FIG. 2, a memory device 100 according to at least one example embodiment may include a memory cell array 130, a peripheral circuit region 160, a voltage generator 120, and the like, but is not limited thereto. The peripheral circuit region 160 may include a row decoder 140, a page buffer circuit 150, a control logic circuit 110, and the like, but is not limited thereto. The memory device 100 may receive a command/address signal CMD/ADDR, a control signal CTRL, and/or a data signal DATA, etc., from an external memory controller. As an example, the memory device 100 may be a NAND flash memory, a vertical NAND flash memory (hereinafter referred to as ‘VNAND’), or the like, but the example embodiments are not limited thereto. In addition, the memory device 100 according to at least one example embodiment may be implemented in a three-dimensional array structure, but is not limited thereto. According to some example embodiments, one or more of the row decoder 140, the page buffer circuit 150, the control logic circuit 110, etc., may be implemented as processing circuitry. The processing circuitry may include hardware or hardware circuit including logic circuits; a hardware/software combination such as a processor executing software and/or firmware; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc., but is not limited thereto.

The memory cell array 130 may include a plurality of memory cell blocks BLK1 to BLKn. Each of the memory cell blocks BLK1 to BLKn may include a plurality of memory cells. The memory cell blocks BLK1 to BLKn may be connected to the peripheral circuit region through bit lines BL, word lines WL, at least one string select line SSL, and at least one ground select line GSL. Specifically, the memory cell blocks BLK1 to BLKn may be connected to the row decoder 140 via the word lines WL, the at least one string select line SSL, and the at least one ground select line GSL. In addition, the memory cell blocks BLK1 to BLKn may be connected to the page buffer circuit 150 through the bit lines BL.

The control logic circuit 110 may receive the address signal ADDR, the command signal CMD, the control signal CTRL, or the like, from the external memory controller, and may transmit and/or receive the data signal DATA, etc.

The voltage generator 120 may include a pump system 121, and may receive an external power voltage EVC to generate various internal power voltages IVC desired and/or required for operation of at least one circuit included in the peripheral circuit region 160 and/or operation of the memory device 100, etc.

The control logic circuit 110 may be connected to the voltage generator 120, the row decoder 140, the page buffer circuit 150, or the like. The control logic circuit 110 may control an overall operation of the memory device 100. The control logic circuit 110 may generate various internal control signals used within the memory device 100 in response to the control signal CTRL. For example, the control logic circuit 110 may control the row decoder 140 to adjust a voltage level provided to the word lines WL when performing a memory operation such as a program operation, a read operation, an erase operation, or the like, and may also control the page buffer circuit 150 to adjust a voltage level provided to the bit lines BL, etc.

The row decoder 140 may select at least one of the plurality of memory cell blocks BLK1 to BLKn in response to a row address signal (ROW_ADDR) received from the control logic circuit 110, and may select at least one word line WL, at least one string select line SSL, and at least one ground select line GSL of the selected memory cell blocks BLK1 to BLKn. The row decoder 140 may transmit a voltage for performing the memory operation to the word line WL of the selected memory cell block BLK1 to BLKn.

The page buffer circuit 150 may be connected to the memory cell array 130 via bit lines BL. The page buffer circuit 150 may operate as a write driver and/or a sense amplifier. For example, during a program operation, the page buffer circuit 150 may operate as a write driver, to apply a voltage according to data to be stored in the memory cell array 130 to the bit line BL. During a read operation, the page buffer circuit 150 may operate as a sense amplifier to sense data stored in the memory cell array 130.

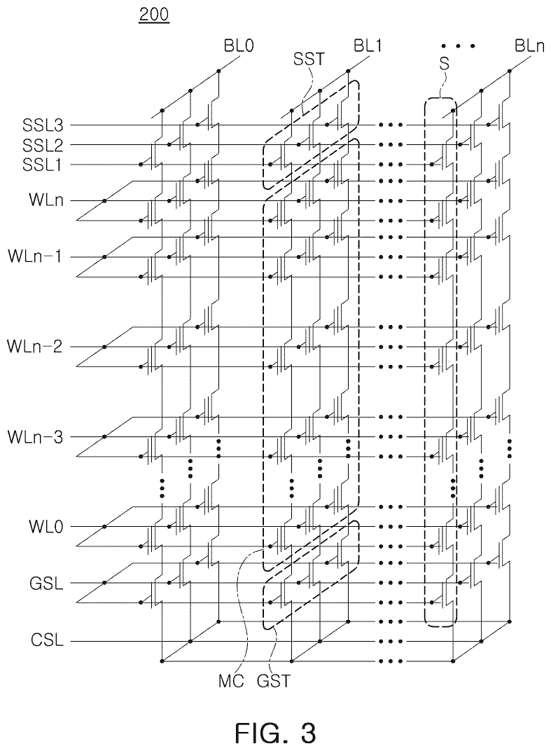

FIG. 3 is a circuit diagram illustrating an example memory block according to at least one example embodiment.

A memory block 200 according to at least one example embodiment may include a plurality of memory cell strings S, and at least a portion of the memory cell strings S may share a plurality of word lines WL0 to WLn and/or a plurality of bit lines BL0 to BLn. Each of the memory cell strings S may include a plurality of memory cells MC connected in series between a string select transistor SST and a ground select transistor GST. The string select transistor SST may be connected to one of bit lines BL1 to BLn in an upper portion of the memory cell string S. A common source line CSL may be electrically connected to an impurity region formed on a substrate (e.g., a semiconductor substrate, etc.). The memory cells MC included in each of the memory cell strings S may share one channel layer.

Gate electrodes of the plurality of memory cells MC may be connected to the word lines WL0 to WLn, respectively. In addition, a gate electrode of the ground select transistor GST may be connected to a ground select line GSL, and a gate electrode of the string select transistor SST may be connected to one of string select lines SSL1 to SSL3. In at least one example embodiment, at least one dummy word line (e.g., DUM1 and DUM2, etc.) may be further included between the plurality of word lines WL0 to WLn, between the plurality of word lines WL0 to WLn and the string select lines SSL1 to SSL3, and/or between the plurality of word lines WL0 to WLn and the ground select line GSL.

The ground select line GSL, the word lines WL0 to WLn, and the string select lines SSL1 to SSL3 may be stacked in a direction perpendicular to an upper surface of the substrate, but is not limited thereto. The ground select line GSL, the word lines WL0 to WLn, and the string select lines SSL1 to SSL3 may be penetrated by a plurality of channel layers. The plurality of channel layers may be connected to one of the bit lines BL0 to BLn.

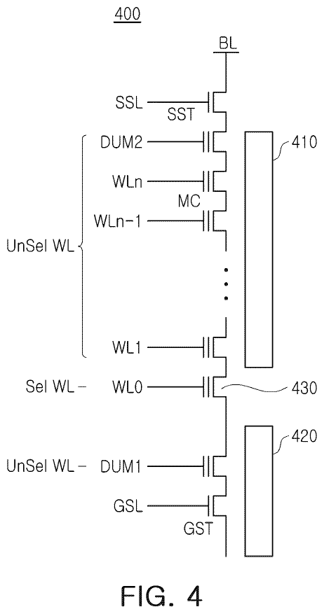

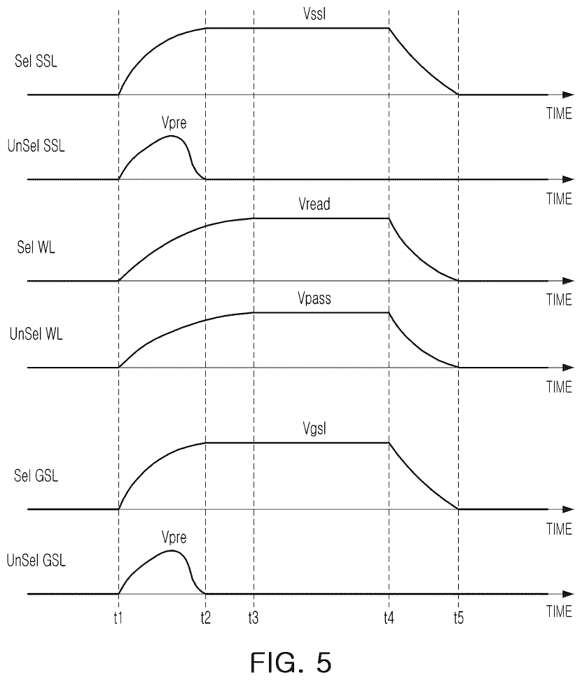

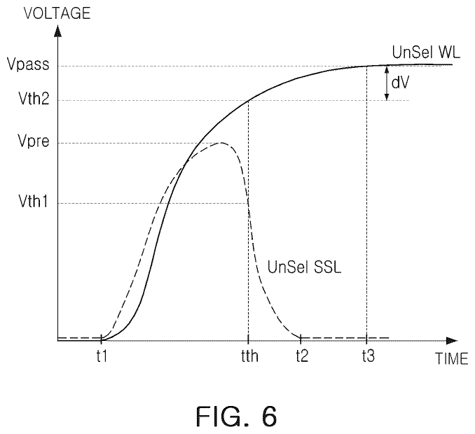

FIG. 4 is a circuit diagram illustrating an example portion of a memory block according to at least one example embodiment. FIGS. 5 and 6 are views illustrating an example read operation according to at least one example embodiment.

A portion 400 of a memory block according to at least one example embodiment described with reference to FIG. 4 may be a circuit diagram for a memory cell string S according to at least one example embodiment, as described with reference to FIG. 3, but the example embodiments are not limited thereto. Referring to FIG. 4, a memory cell string 400 may include a plurality of memory cells MC connected in series between a string select transistor SST and a ground select transistor GST. The string select transistor SST may be connected to a bit line BL in an upper portion of the memory cell string 400.

Gate electrodes of the plurality of memory cells MC may be respectively connected to word lines WL0 to WLn. In addition, a gate electrode of the ground select transistor GST may be connected to a ground select line GSL, and a gate electrode of the string select transistor SST may be connected to a string select line SSL. In at least one example embodiment, at least one dummy word line (e.g., DUM1 and DUM2, etc.) may be connected to the gate electrode of the memory cell MC between a plurality of word lines WL0 to WLn, between the plurality of word lines WL0 to WLn and the string select line SSL, and/or between the plurality of word lines WL0 to WLn and the ground select line GSL.

Referring to FIG. 5, a read operation may be performed through a pre-charge operation, a reading operation, and/or a recovery operation, etc. The pre-charge operation may be performed in a first section (e.g., t1 to t3), the read operation may be performed in a second section (e.g., t3 to t4), and the recovery operation may be performed in a third section (e.g., t4 to t5), but the example embodiments are not limited thereto.

In the first section (e.g., t1 to t3) in which the pre-charge operation is performed, a pre-pulse voltage Vpre may be commonly applied to all of the word lines before performing the read operation. Through this, each of the word lines may be quickly switched to a voltage level that each of the word lines should reach in the second section (e.g., t3 to t4) in which the read operation is performed. After the pre-pulse voltage Vpre is applied, each of the word lines may be raised or lowered to the voltage level that should be reached for the read operation.

In the second section (e.g., t3 to t4) in which the read operation is performed, a string select voltage Vssl may be applied to the string select line SSL of the memory cell string including at least one memory cell which is a target of the read operation, among a plurality of memory cell strings, and a ground voltage may be input to the string select lines SSL of a remaining memory cell string. A read voltage Vread may be applied to a selected word line Sel WL connected to a memory cell MC to be the target of the read operation, among a plurality of word lines, and a pass voltage Vpass may be applied to an unselected word line UnSel WL connected to a remaining memory cell MC. For example, the pass voltage Vpass may have a higher level than the read voltage Vread. A ground select voltage Vgsl may be applied to the ground select line GSL of the memory cell string that may include a memory cell to be the target of the read operation among the plurality of memory cell strings, and the ground voltage may be input to the ground select lines GSL of the remaining memory cell string. In the third section (e.g., t4 to t5) in which the recovery operation is performed, the ground voltage may be applied to all of the word lines simultaneously, thereby terminating the read operation.

FIG. 6 may be a graph comparing voltage levels of an unselected string select line UnSel SSL and an unselected word line UnSel WL over time in a first section (e.g., t1 to t3) of a read operation, as described with reference to FIG. 5. Referring to FIG. 6, during a pre-pulse section (e.g., t1 to tth), a voltage level of an unselected string select line UnSel SSL may rise to a pre-pulse voltage Vpre and then fall to a ground voltage level.

In a pre-charge operation, in the unselected string select line UnSel SSL, during the pre-pulse section (e.g., t1 to tth), the pre-pulse voltage Vpre may be applied, and a ground voltage may be applied. In at least one example embodiment depending on and/or based on the driving capability of a word line voltage generator, a section (e.g., t1 to t2) during which a voltage level of the unselected string select line UnSel SSL reaches a ground voltage after reaching the pre-pulse voltage Vpre may be longer than the pre-pulse section (e.g., t1 to tth). For example, a voltage level (Vth1) of the unselected string select line UnSel SSL may be higher than a ground voltage level at a point in time (e.g., tth) when the pre-pulse section ends. In at least one other example embodiment, a voltage level of an unselected word line UnSel WL may be additionally increased by an additional rising voltage dV after the pre-pulse section (e.g., t1 to tth) until a point in time (e.g., t3) when the pre-charge operation ends.

In the pre-charge operation, a magnitude of the additional rising voltage dV of the unselected word line UnSel WL may be changed depending on and/or based on the driving capability of the word line voltage generator. For example, when a level of an external power supply voltage decreases (e.g., when the voltage level provided by the external power supply decreases, etc.), the driving capability of the word line voltage generator may decrease, and a period of time for the word line voltage generator to generate a setting voltage may increase. Therefore, a period of time (e.g., t1 to t3) taken for the unselected word line Unsel WL to converge to a pass voltage Vpass may also increase, and accordingly, the magnitude of the additional rising voltage dV of the unselected word line UnSel WL may increase.

Referring to FIG. 4 and FIG. 5, when the read operation is performed, the pass voltage Vpass may be applied to the unselected word lines UnSel WL and the read voltage Vread may be applied to the selected word lines Sel WL at a point in time (e.g., t3) when the pre-charge operation ends. In addition, the ground voltage may be applied to the unselected string select line UnSel SSL, and the ground select voltage Vgsl may be applied to the selected ground select line. In this case, in a channel layer of the memory cell string 400, an upper section 410 adjacent to the unselected string select line UnSel SSL may experience channel boosting due to the pass voltage Vpass applied to the unselected word line UnSel WL. Therefore, the voltage level of the upper section 410 of the channel layer may increase. A ground voltage may be applied to a lower section 420 of the channel layer of the memory cell string 400, as the ground select transistor GST is turned on.

Therefore, when the read operation is performed, a voltage difference may occur and/or may be observed between the upper section 410 and the lower section 420 in one channel layer. In particular, as described with reference to FIG. 6, when the voltage level of the unselected word line UnSel WL increases by the additional rising voltage dV, the voltage difference in one channel layer may increase. In this case, an HCI phenomenon may occur in a specific memory cell 430, and data stored in the specific memory cell 430 may be lost and/or may have an error, etc.

According to at least one example embodiment, a multi-stage charge pump circuit may output a pump voltage based on a pump clock signal, and a period of the pump clock signal may be determined depending on and/or based on a level of an external power supply voltage. For example, an interval at which the pump voltage output by the multi-stage charge pump circuit is pumped may be determined depending on and/or based on a magnitude of the external power supply voltage. In this case, regardless of the voltage level of the external power supply voltage, a change in time at which the word line voltage generator generates a setting voltage may be decreased and/or minimized, thereby reducing and/or preventing the data stored in a memory cell MC from being lost and/or having an error, etc.

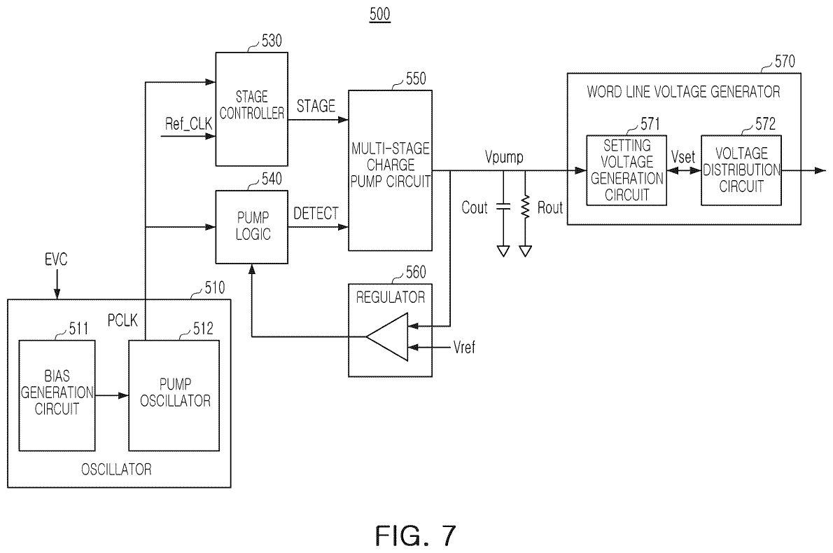

FIG. 7 is a block diagram illustrating an example voltage generator according to at least one example embodiment.

Referring to FIG. 7, a voltage generator 500 according to at least one example embodiment may include an oscillator 510, a stage controller 530, a multi-stage charge pump circuit 550, a pump logic 540, a regulator 560, a word line voltage generator 570, and the like, but the example embodiments are not limited thereto. The voltage generator 500 may receive an external power supply voltage EVC, and may output a word line voltage to a row decoder, etc. The row decoder may transmit the word line voltage to a plurality of word lines connected to memory cell blocks in response to a row address signal received from a control logic circuit. The word line voltage may include a string select voltage Vssl, a pre-pulse voltage Vpre, a read voltage Vread, a pass voltage Vpass, and/or a ground select voltage Vgsl, or the like, which were described above with reference to FIG. 5. According to some example embodiments, one or more of the oscillator 510, the stage controller 530, the multi-stage charge pump circuit 550, the pump logic 540, the regulator 560, and/or the word line voltage generator 570, etc., may be implemented as processing circuitry.

The oscillator 510 may include a bias generation circuit 511, a pump oscillator 512, and the like, but is not limited thereto. The oscillator 510 may receive the external power supply voltage EVC, and may output a pump clock signal PCLK to the stage controller 530 and the pump logic 540 (e.g., pump logic circuitry, etc.). The pump clock signal PCLK may be a clock signal serving as a reference for the operation of the voltage generator 500, but is not limited thereto.

The stage controller 530 may output a reference clock signal Ref_CLK, and/or a stage signal STAGE based on the pump clock signal PCLK from the oscillator 510 to the multi-stage charge pump circuit 550. The stage signal STAGE may synchronize with a period of the pump clock signal PCLK to have a different data value. In addition, the stage signal STAGE may be output to the multi-stage charge pump circuit 550 by synchronizing with the period of the pump clock signal PCLK.

The multi-stage charge pump circuit 550 may output a pump voltage Vpump to the word line voltage generator 570 based on the stage signal STAGE received from the stage controller 530 and a control signal DETECT received from the pump logic 540. The pump voltage Vpump may have a plurality of stages, and levels of the pump voltage Vpump may be different for each stage, but is not limited thereto. The levels of the stages of the pump voltage Vpump may be determined according to and/or based on the stage signal STAGE received by the multi-stage charge pump circuit 550. The multi-stage charge pump circuit 550 may perform a pump operation based on the control signal DETECT. In this case, the pump operation may include the increasing of a level of the pump voltage Vpump in order to pass from one stage to another stage. For example, when the control signal DETECT is on a high (HIGH) level, the multi-stage charge pump circuit 550 may perform a pump operation to increase the level of the pump voltage Vpump. Conversely, when the control signal DETECT is on a low (LOW) level, the multi-stage charge pump circuit 550 may stop the pump operation to maintain the level of the pump voltage Vpump constant.

The regulator 560 may transmit a feedback signal to the pump logic 540 based on a result of comparing a level of the pump voltage Vpump and a level of the reference voltage Vref. The pump logic 540 may determine the control signal DETECT based on the pump clock signal PCLK transmitted from the oscillator and the feedback signal transmitted from the regulator 560. For example, when the level of the pump voltage Vpump is lower than a voltage level of the reference voltage Vref at a specific stage, the level of the pump voltage Vpump may be increased by outputting a high-level control signal DETECT to the multi-stage charge pump circuit 550. Conversely, when the level of the pump voltage Vpump is higher than the voltage level of the reference voltage Vref at a specific stage, the level of the pump voltage Vpump may be maintained by outputting a low-level control signal DETECT to the multi-stage charge pump circuit 550.

The word line voltage generator 570 may include a setting voltage generation circuit 571, a voltage distribution circuit 572, and the like, but is not limited thereto. The setting voltage generation circuit 571 may receive the pump voltage Vpump to generate a setting voltage Vset, which may be a reference voltage for determining an operating voltage of a word line, and may output the same to the voltage distribution circuit 572, but the example embodiments are not limited thereto. The voltage distribution circuit 572 may receive the setting voltage Vset and may output a word line voltage to the row decoder. The pump voltage may pass through a path including at least one capacitor Cout and/or at least one resistor Rout in a process of being transmitted to the word line voltage generator 570. However, the example embodiments of the inventive concepts are not limited thereto.

The oscillator 510 may determine and may output a period of the pump clock signal PCLK depending on and/or based on a level of the external power supply voltage EVC. The stage controller 530 may output the stage signal STAGE to the multi-stage charge pump circuit 550 in units of the period of the pump clock signal PCLK. The multi-stage charge pump circuit 550 may include a plurality of unit circuits (e.g., a plurality of pump subcircuits, etc.), and a point in time at which each of the unit circuits is enabled may be determined by the stage signal STAGE. For example, a delay period of time between points in time at which the unit circuits (e.g., pump subcircuits, etc.) are respectively enabled may be determined depending on and/or based on a magnitude of the external power supply voltage EVC, and accordingly, an interval at which the multi-stage charge pump circuit 550 pumps may be determined depending on and/or based on a magnitude of the external power supply voltage EVC, but the example embodiments are not limited thereto. For example, as a level of the external power supply voltage EVC decreases, a period of the pump clock signal PCLK may decrease, and accordingly, the multi-stage charge pump circuit 550 may generate the pump voltage Vpump faster and transmit the pump voltage Vpump to the word line voltage generator 570. Through this, the word line voltage generator 570 may maintain a time for generating the setting voltage Vset on a constant level, thereby suppressing a level of the unselected word line voltage from additionally and/or undesirably increasing during the pre-charge operation. Therefore, a voltage difference of the channel layer by channel boosting may be reduced to reduce and/or prevent data stored in the memory cell from being damaged and/or from having errors.

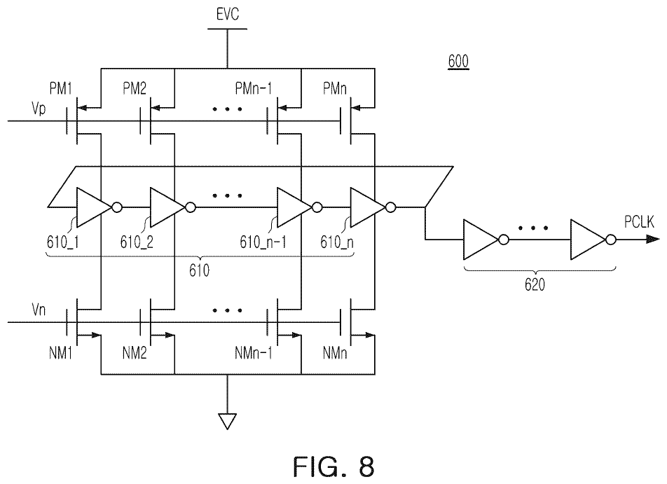

FIG. 8 is a block diagram illustrating an example pump oscillator according to at least one example embodiment.

Referring to FIG. 8, a pump oscillator 600 according to at least one example embodiment may include a plurality of buffer circuits 610_1 to 610_n, a plurality of PMOS transistors PM1 to PMn, and/or a plurality of NMOS transistors NM1 to NMn, etc., but the example embodiments are not limited thereto. The pump oscillator 600 may have a structure in which the plurality of PMOS transistors PM1 to PMn, the plurality of buffer circuits 610_1 to 610_n, and/or the plurality of NMOS transistors NM1 to NMn are connected in series between an external power supply voltage EVC and a ground voltage, but are not limited thereto. Each of the PMOS transistors PM1 to PMn, the buffer circuits 610_1 to 610_n, and/or the NMOS transistors NM1 to NMn, etc., may be combined and operated as a single sub-circuit, but the example embodiments are not limited thereto. The plurality of buffer circuits 610_1 to 610_n connected in series may have both ends connected to each other to form a buffering structure 610.

The plurality of PMOS transistors PM1 to PMn may electrically connect each of the plurality of buffer circuits 610 to the external power supply voltage EVC in response to a first bias Vp. The plurality of NMOS transistors NM1 to NMn may electrically connect each of the plurality of buffer circuits 610 to the ground voltage in response to a second bias Vn. A frequency of a pump clock signal PCLK may be changed depending on and/or based on the voltage levels of at least one bias voltages, e.g., a level of the first bias Vp and a level of the second bias Vn, etc., but the example embodiments are not limited thereto. For example, as the level of the first bias Vp increases, the frequency of the pump clock signal PCLK output by the pump oscillator 600 may decrease. As another example, as the level of the second bias Vn increases, the frequency of the pump clock signal PCLK output by the pump oscillator 600 may increase. However, the example embodiments are not limited thereto.

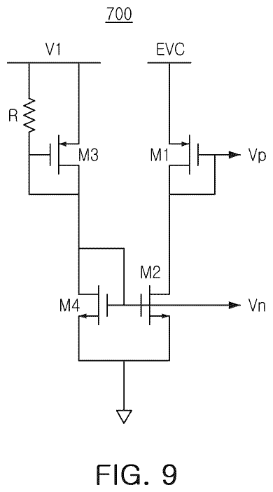

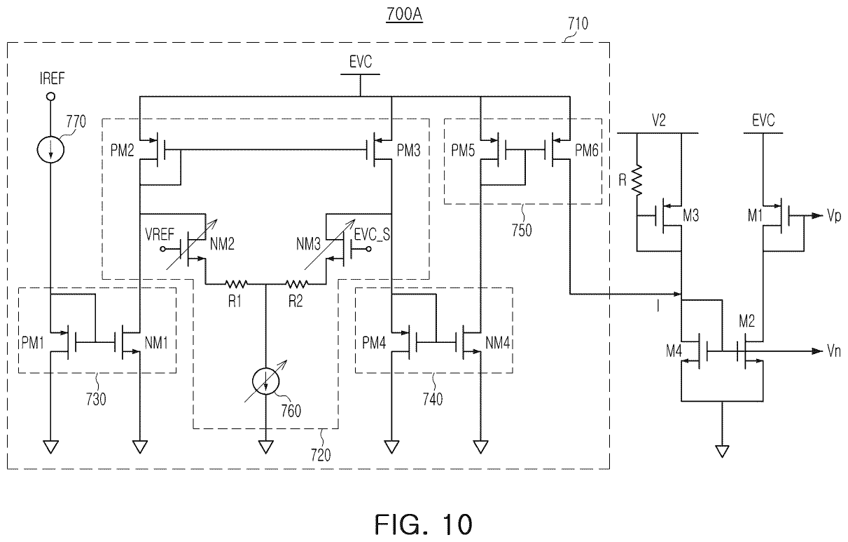

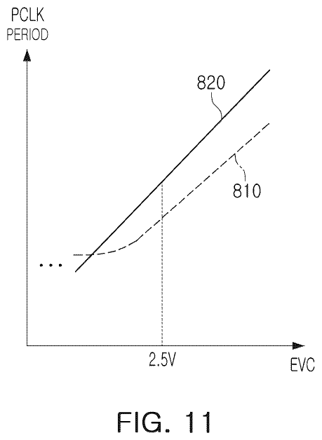

FIGS. 9 and 10 are circuit diagrams illustrating an example bias generation circuit according to at least one example embodiment. FIG. 11 is a view illustrating an example operation of an oscillator according to at least one example embodiment.

Referring to FIG. 9, a bias generation circuit 700 according to at least one example embodiment may have a first transistor M1 and a second transistor M2 connected in series between an external power supply voltage EVC and/or a ground voltage, etc., but is not limited thereto. In addition, a third transistor M3 and a fourth transistor M4 may have a structure connected in series between a first voltage V1 and/or the ground voltage, but the example embodiments are not limited thereto. In at least one example embodiment, the first transistor M1 and the third transistor M3 may be PMOS transistors, and the second transistor M2 and the fourth transistor M4 may be NMOS transistors, but are not limited thereto.

A gate terminal of the first transistor M1, a gate terminal of the third transistor M3, and/or a gate terminal of the fourth transistor M4 may be connected to a source terminal, but they are not limited thereto. In at least one example embodiment, a resistor R may be connected between a gate terminal and a drain terminal of the third transistor M3, but is not limited thereto. A first bias Vp may be output to a source terminal of the first transistor M1, and/or a second bias Vn may be output to a source terminal of the fourth transistor M4.

In at least one example embodiment, a level of the first voltage V1 may be controlled to adjust a ratio between a voltage level of the first bias Vp and a voltage level of the second bias Vn. For example, when the level of the first voltage V1 increases, the level of the second bias voltage Vn may increase.

A bias generation circuit 700A according to at least one example embodiment described with reference to FIG. 10 may have a structure in which an auxiliary bias generation circuit 710 is further connected, as compared to the bias generation circuit 700 according to at least one example embodiment described with reference to FIG. 9, but the example embodiments are not limited thereto. The auxiliary bias generation circuit 710 may be a circuit additionally supplying an auxiliary current I to an output terminal outputting a second bias Vn in the bias generation circuit 700 described with reference to FIG. 9, but is not limited thereto.

The auxiliary bias generation circuit 710 may be comprised of a plurality of current mirrors, e.g., current mirrors 730, 740, and/or 750, etc., a differential amplifier 720 formed with current mirrors, and the like, but the example embodiments are not limited thereto. In at least one example embodiment, a first current mirror 730 may have a structure in which a gate terminal of a first PMOS PM1 and a gate terminal of a first NMOS NM1 are connected and the gate terminal and a source terminal of the first PMOS PM1 are connected, but is not limited thereto. A second current mirror 740 may have a structure in which a gate terminal of a fourth PMOS PM4 and a gate terminal of a fourth NMOS NM4 are connected and the gate terminal and a source terminal of the fourth PMOS PM4 are connected, but is not limited thereto. A third current mirror 750 may have a structure in which a gate terminal of a fifth PMOS PM5 and a gate terminal of a sixth PMOS PM6 are connected and the gate terminal and a drain terminal of the fifth PMOS PM5 are connected, but is not limited thereto.

The differential amplifier 720 may have a structure in which PMOSs (e.g., PM2 and PM3), NMOSs (e.g., NM2 and NM3), resistors (e.g., R2 and R3), and/or a tail current source 760 may be connected in series between an external power supply voltage EVC and a ground voltage, and a gate terminal of a second PMOS and a gate terminal of a third PMOS may be connected to each other, etc., but is not limited thereto. A gate terminal of a second NMOS may receive a reference voltage VREF, and a gate terminal of a third NMOS NM3 may receive a sub-external power supply voltage EVC_S, but are not limited thereto. The sub-external power supply voltage EVC_S may be a value output by dividing the external power supply voltage EVC, and may have a level proportional to a level of the external power supply voltage EVC.

A reference current source 770 supplying a reference current IREF to a source terminal of the first PMOS PM1 may be connected. The auxiliary bias generation circuit 710 may amplify the reference current IREF in proportion to a difference between the reference voltage VREF and the sub-external power supply voltage EVC_S, and may additionally supply the same to an output terminal of the second bias Vn. A magnitude of the auxiliary current I additionally supplied to the output terminal of the second bias Vn may be changed depending on and/or based on a level of the sub-external power supply voltage EVC_S and a magnitude of current output by the tail current source 760. For example, a magnitude of the auxiliary current I supplied by the auxiliary bias generation circuit 710 to the output terminal of the second bias Vn may be changed depending on and/or based on the level of the external power supply voltage EVC.

Referring to FIG. 11, a graph of FIG. 11 may be a graph for a first pump clock signal 810 that the pump oscillator 600 of FIG. 8 outputs by receiving the first bias voltage Vp and the second bias voltage Vn from the bias generation circuit 700 of FIG. 9, and a second pump clock signal 820 that the pump oscillator 600 of FIG. 8 outputs by receiving the first bias voltage Vp and the second bias voltage Vn from the bias generation circuit 700A of FIG. 10.

Referring to FIGS. 8 to 10, a pump clock signal PCLK having a specific period may be output, as the first bias voltage Vp and the second bias voltage Vn are input to the pump oscillator 600. As the level of the external power supply voltage EVC changes, the period of the pump clock signal PCLK may be changed. In at least one example embodiment, when the level of the external power supply voltage EVC is lowered below a desired voltage threshold, e.g., 2.5 V, the period of the first pump clock signal 810 may decrease non-linearly. On the other hand, when the level of the external power supply voltage EVC is lowered below the desired voltage threshold, e.g., 2.5 V, the period of the second pump clock signal 820 may decrease linearly, as compared to the first pump clock signal 810. For example, when the auxiliary bias generation circuit 710 of FIG. 9 additionally supplies the auxiliary current I to the output terminal of the second bias Vp, the oscillator may output the pump clock signal PCLK of which period is changed linearly with respect to a change in the external power supply voltage EVC.

Therefore, a delay time between time points at which a multi-stage charge pump circuit is pumped may be changed linearly depending and/or based on the magnitude of the external power supply voltage EVC. For example, a word line voltage generator may maintain a change in time for generating a setting voltage constant regardless of a change in the external power supply voltage EVC. Therefore, a level of an unselected word line voltage during the pre-charge operation may be suppressed from further increasing, a voltage difference in a channel layer due to channel boosting may be reduced, and/or data stored in the memory cell may be reduced and/or prevented from being damaged, from containing errors, etc.

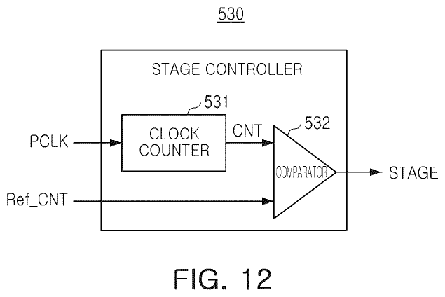

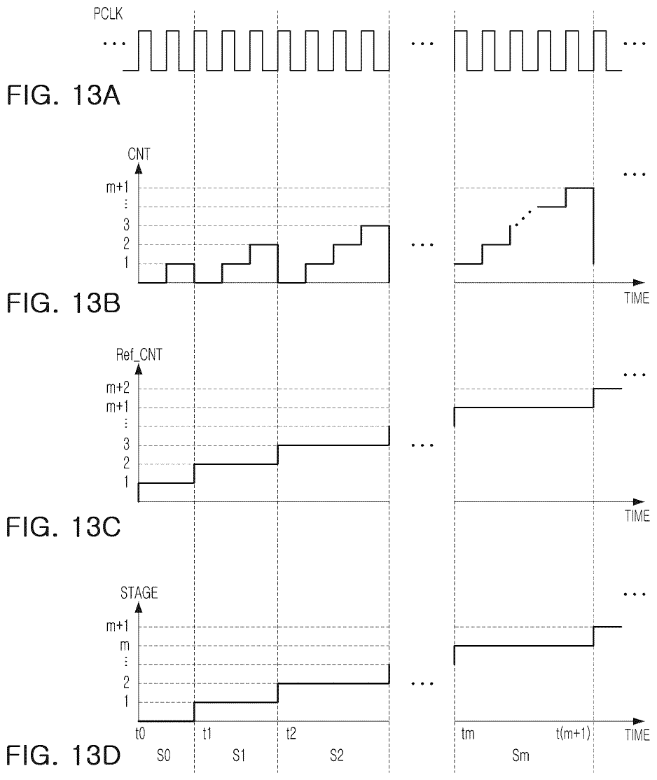

FIG. 12 is a block diagram illustrating an example stage controller according to at least one example embodiment. FIGS. 13A, 13B, 13C, and 13D are views illustrating an operation of a stage controller according to at least one example embodiment.

In at least one example embodiment, a data value of a stage signal STAGE may be changed based on a pump clock signal PCLK. In addition, the stage signal STAGE may be output to a multi-stage charge pump circuit 550 based on the pump clock signal PCLK.

Referring to FIG. 12, a stage controller 530 according to at least one example embodiment may include a clock counter 531, a comparator 532, and the like. The clock counter 531 may count the number of cycles of a pump clock signal PCLK, and may output a count signal CNT having a data value representing a count value to the comparator 532. The comparator 532 may compare the count signal CNT and a reference clock signal Ref_CNT, and may output a stage signal STAGE to a multi-stage charge pump circuit 550. In at least one example embodiment, when a data value of the count signal CNT is equal to a data value of the reference clock signal Ref_CNT, the comparator 532 may output the stage signal STAGE, including the data value, to the multi-stage charge pump circuit 550.

Referring to FIG. 7 and FIG. 12, FIG. 13A may be a graph for a pump clock signal PCLK output by an oscillator 510. The pump clock signal PCLK may be used as a basic signal synchronizing at least one internal circuit of a voltage generator 500 and/or driving the operation of the voltage generator 500, but the example embodiments are not limited thereto.

FIG. 13B may be a graph illustrating a data value of a count signal CNT output by counting the number of cycles of a pump clock signal PCLK by a clock counter 531, over time. FIG. 13C may be a graph illustrating a data value of a reference count signal Ref_CLK input to a comparator 532, over time. FIG. 13D may be a graph illustrating a data value of a stage signal STAGE output by comparing a count signal CNT and a reference count signal Ref_CNT by a comparator 532, over time.

A count signal CNT may count the number of cycles of a pump clock signal PCLK, and may increase a data value by 1 (e.g., increment the data value) based on the counted number of cycles. A comparator 532 may output a stage signal STAGE to a multi-stage charge pump circuit 550, the stage signal STAGE including the data value, when the data value of the count signal CNT is equal to a data value of a reference clock signal Ref_CNT. In this case, the data value of the reference clock signal Ref_CNT may increase by 1 (e.g., may be incremented), and the data value of the pump clock signal PCLK may be reset.

The stage signal STAGE may have and/or include a plurality of stages. In at least one example embodiment, when the stage signal STAGE is in an m^{th} stage Sm, the data value of the reference clock signal Ref_CNT may be m+1. In this case, the data value of the count signal CNT increases from an m^{th} time point tm, and at an (m+1)^{th} time point t(m+1), the data value of the reference clock signal Ref_CNT may become the same as (m+1). In this case, the stage signal STAGE may be switched to the (m+1)^{th} stage S(m+1), 1 may be added to the data value of the reference clock signal Ref_CNT, and the count signal CNT may be reset to 0.

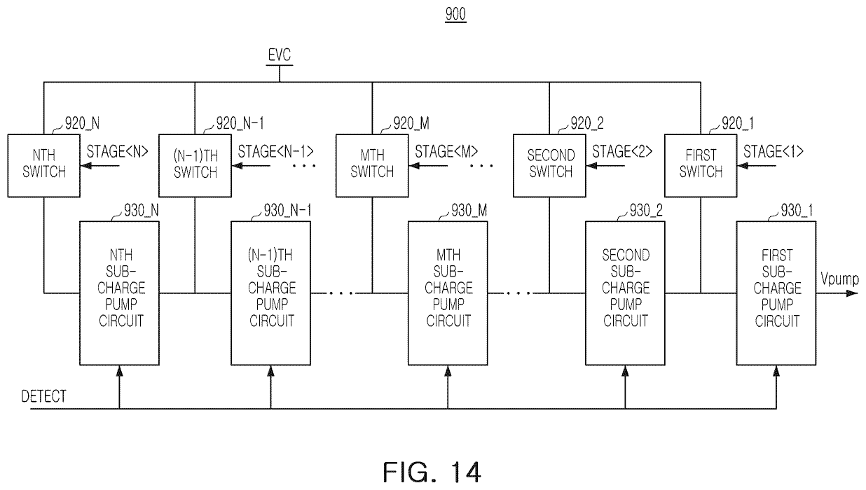

FIG. 14 is a block diagram illustrating an example multi-stage charge pump circuit according to at least one example embodiment.

Referring to FIG. 14, a multi-stage charge pump circuit 900 according to at least one example embodiment may be comprised of a plurality of switches 920_1 to 920_N and/or a plurality of sub-charge pump circuits 930_1 to 930_N, etc., but is not limited thereto. The plurality of sub-charge pump circuits 930_1 to 930_N may be connected in series, and the plurality of switches 920_1 to 920_N may be connected between the sub-charge pump circuits 930_1 to 930_N, but the example embodiments are not limited thereto. The plurality of switches 920_1 to 920_N may supply and/or cut off an external power supply voltage EVC to each of the plurality of sub-charge pump circuits 930_1 to 930_N. The plurality of sub-charge pump circuits 930_1 to 930_N may receive a control signal DETECT. The multi-stage charge pump circuit 900 may output a pump voltage Vpump through at least one sub-charge pump circuit 930_1 to 930_N.

Referring to FIG. 7, a multi-stage charge pump circuit 550 may output a pump voltage Vpump, based on a stage signal STAGE received from a stage controller 530 and/or a control signal DETECT received from a pump logic 540. The pump voltage Vpump may have a plurality of stages, and the voltage levels of pump voltages Vpump in each of the plurality of stages may be different from each other. The stage of the pump voltage Vpump may be determined depending on and/or based on a data value of the stage signal STAGE received by the multi-stage charge pump circuit 550.

The multi-stage charge pump circuit 550 may perform a pump operation based on a control signal DETECT received from a regulator 560. For example, when the control signal DETECT is high, the multi-stage charge pump circuit 550 may perform the pump operation. Conversely, when the control signal DETECT is low, the multi-stage charge pump circuit 550 may stop and/or omit the pump operation. Through this, the pump voltage Vpump may be controlled to maintain a level after reaching a certain and/or desired level.

In at least one example embodiment, a data value corresponding to each digit of the stage signal STAGE may be input to each of the plurality of switches 920_1 to 920_N of the multi-stage charge pump circuit 900. In addition, the number of sub-charge pump circuits 930_1 to 930_N operating in a state connected to the external power supply voltage EVC may be changed depending on and/or based on the stage signal STAGE. For example, a count signal CNT, a reference count signal Ref_CNT, and a stage signal STAGE may be signals CNT<N:1>, Ref_CNT<N:1>, and STAGE<N:1>, respectively having an N-bit data size. In this case, N may be a natural number. An M-digit stage signal STAGE<M> may be input to an M^{th} switch 920_M. In this case, an M^{th} sub-charge pump circuit 930_M may be driven to output the pump voltage Vpump. However, the example embodiments of the inventive concepts are not limited thereto.

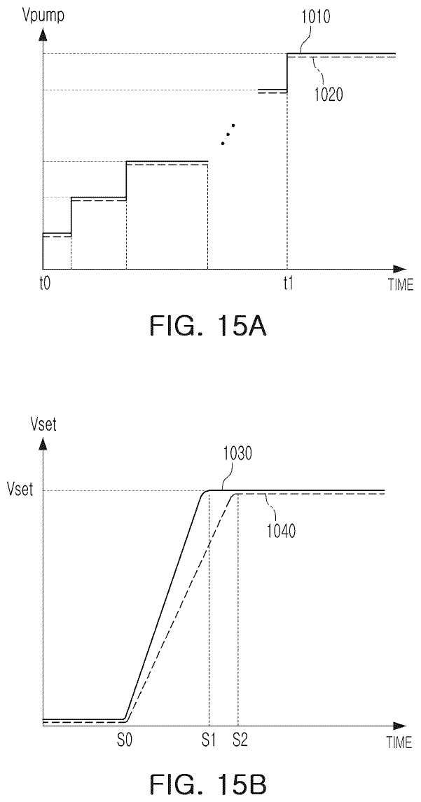

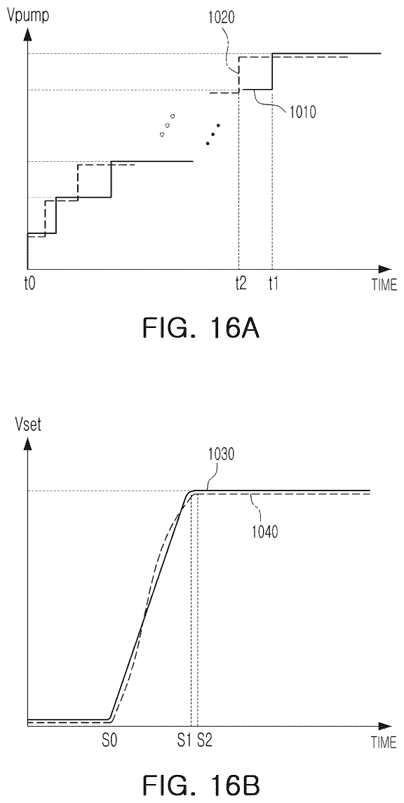

FIGS. 15A, 15B, 16A, and 16B are views illustrating an operation of a word line voltage generator according to at least one example embodiment.

FIG. 15A is a graph illustrating an example process in which a pump voltage Vpump output from a multi-stage charge pump circuit may be pumped through a plurality of stages over time. A first pump voltage 1010 output when a level of an external power supply voltage is high, and a second pump voltage 1020 output when the level of the external power supply voltage is low may have a constant time (e.g., t0 to t1) for which the pump operation is performed. For example, the multi-stage charge pump circuit according to FIG. 15A may generate the pump voltage Vpump over the constant time (e.g., t0 to t1) regardless of the level of the external power supply voltage.

FIG. 15B is a graph illustrating a process of generating a setting voltage Vset based on the first pump voltage 1010 or the second pump voltage 1020, described in FIG. 15A, by a setting voltage generation circuit in a word line voltage generator over time. A time (e.g., S0 to S2) for generating a second setting voltage 1040 generated based on the second pump voltage 1020 may take longer than a time (e.g., S0 to S1) for generating a first setting voltage 1030 generated based on the first pump voltage 1010.

FIG. 16A is a graph illustrating a process of pumping a pump voltage Vpump through a plurality of stages from a multi-stage charge pump circuit over time. A time (e.g., t0 to t2) for performing a pumping operation for a second pump voltage 1020 output when a level of an external power supply voltage is low may be shorter than a time (e.g., t0 to t1) for performing a pumping operation for a first pump voltage 1010 output when the level of the external power supply voltage is low. For example, the multi-stage charge pump circuit according to FIG. 15A may generate the pump voltage Vpump more quickly as the level of the external power supply voltage decreases.

FIG. 16B is a graph illustrating a process of generating a setting voltage Vset based on the first pump voltage 1010 or the second pump voltage 1020, described in FIG. 16A, by a setting voltage generation circuit in a word line voltage generator over time. A time (e.g., S0 to S2) for generating a second setting voltage 1040 based on a second pump voltage 1020 in FIG. 16B may be further reduced, as compared to the time (e.g., S0 to S2) for generating the second setting voltage 1040 in FIG. 15B. For example, a change in time for generating the setting voltage Vset by the word line voltage generator according to and/or based on one or more of the example embodiments of FIGS. 16A and 16B may be further reduced, as compared to the word line voltage generator according to and/or based on one or more of the example embodiments of FIGS. 15A and 15B. For example, a change in time for generating the setting voltage Vset by the word line voltage generator according to and/or based on one or more of the example embodiments of FIGS. 16A and 16B may be reduced regardless of a change in external power supply voltage.

When performing a read operation on a memory cell string, a magnitude of an additional rising voltage of an unselected word line may be changed depending on and/or based on the driving capability of a word line voltage generator during a pre-charge operation. Referring to FIGS. 15A and 15B, a multi-stage charge pump circuit may generate a pump voltage Vpump for a desired and/or predetermined time period regardless of a pump clock signal. In this case, when a level of an external power supply voltage EVC decreases, the driving capability of a word line voltage generator may decrease, and a time period for generating the set voltage may increase. Therefore, a time (e.g., t1 to t3) taken for an unselected word line Unsel WL to converge to a pass voltage Vpass may also increase, and accordingly, a magnitude of an additional rising voltage dV of the unselected word line UnSel WL may increase further. In this case, as described with reference to FIG. 4 and FIGS. 15A and 15B, a high voltage difference may occur between upper and lower sections in one channel layer. Therefore, an HCI phenomenon may occur in a memory cell, and data stored in the memory cell may be lost, may develop an error, may be incorrect, etc.

Referring to FIGS. 16A and 16B, a multi-stage charge pump circuit according to at least one example embodiment may output at least one pump voltage based on a pump clock signal, and a period of the pump clock signal may be determined depending on and/or based on a level of an external power supply voltage. For example, a delay time between points at which the multi-stage charge pump circuit is pumped may be determined depending on and/or based on a magnitude of the external power supply voltage. In this case, the word line voltage generator according to at least one example embodiment may decrease and/or minimize a change in time for generating the setting voltage Vset regardless of the level of the external power supply voltage. Therefore, a voltage difference between upper and lower sections in one channel layer may be reduced, and thus an HCI phenomenon may occur in a memory cell may be decreased and/or prevented, thereby decreasing and/or preventing data stored in the memory cell from being lost.

According to at least one example embodiment, an oscillator may output a pump clock signal for which a period (e.g., a time period) is determined depending on and/or based on a level of an external power supply voltage, and a delay time between points at which a plurality of unit circuits of a multi-stage charge pump circuit are enabled may be determined depending on and/or based on a magnitude of the external power supply voltage. For example, a pumping interval of a pump voltage output by a multi-stage charge pump circuit may be determined depending on and/or based on a level of an external power supply voltage. Through this, a word line voltage generator may decrease and/or minimize a change in time for generating a setting voltage regardless of a change in the external power supply voltage, thereby reducing an additional increase amount of an unselected word line voltage during a pre-charge operation. Therefore, loss of data (and/or errors in data) stored in a memory cell may be decreased and/or prevented by reducing a voltage difference generated in a channel layer by channel boosting.

Various advantages and effects of the example embodiments of the inventive concepts are not limited to the above-described contents, and will be more easily understood in the process of explaining specific example embodiments.

While some example embodiments have been illustrated and described above, it will be apparent to one of ordinary skill in the art that modifications and variations could be made without departing from the scope of the inventive concepts as defined by the appended claims.

What is claimed is:

1. A voltage generator comprising:
an oscillator configured to outputting a pump clock signal of which a frequency is determined depending on a level of an external power supply voltage;
a stage controller configured to,
count a number of cycles of the pump clock signal, and
output a stage signal based on a data value of a reference count signal and the counted number of cycles of the pump clock signal;
a multi-stage charge pump circuit configured to,
determine an enable time period based on the stage signal and a magnitude of the external power supply voltage, and
perform a pump operation based on a control signal and the determined enable time period; and
a word line voltage generator configured to output a word line voltage based on a pump voltage.

2. The voltage generator of claim 1, further comprising:
a voltage regulator configured to generate a feedback voltage based on the pump voltage and a reference voltage.

3. The voltage generator of claim 2, further comprising:
a pump logic circuit configured to,
receive the pump clock signal and the feedback voltage,
generate the control signal based on the feedback voltage, and output the control signal to the multi-stage charge pump circuit.

4. The voltage generator of claim 1, wherein
in response to the counted number of cycles of the pump clock signal being equal to the data value of the reference count signal, the stage controller is further configured to output the counted number of cycles of the pump clock signal as the stage signal.

5. The voltage generator of claim 1, wherein the oscillator is further configured to:
generate a first bias voltage and a second bias voltage based on the external power supply voltage, the first bias voltage having a level based on a level of the external power supply voltage.

6. The voltage generator of claim 5, wherein the oscillator is further configured to:
receive a reference voltage and the external power supply voltage; and
generate the first bias voltage based on the reference voltage and the external power supply voltage.

7. A memory device comprising:
a memory cell array including a plurality of cell strings, the plurality of cell strings including a plurality of memory cells and a plurality of word lines, the plurality of memory cells respectively connected between a plurality of string select lines and a plurality of ground select lines, and the plurality of word lines connected to the plurality of memory cells;
a control logic circuit configured to perform at least one read operation by controlling a row voltage supplied to the plurality of string select lines, the plurality of word lines, and the plurality of ground select lines;
a voltage generator configured to output a pump clock signal, the outputting of the pump clock signal including setting a frequency of the pump clock signal based on a level of an external power supply voltage;
a stage controller configured to,
count a number of cycles of the pump clock signal, and
output a stage signal based on a data value of a reference count signal and the counted number of cycles of the pump clock signal;
a multi-stage charge pump circuit configured to,
determine one or more enable time periods based on the stage signal and a magnitude of the external power supply voltage, and
perform a pump operation based on a control signal and the determined one or more enable time periods; and
a word line voltage generator configured to output a word line voltage based on a pump voltage.

8. The memory device of claim 7, wherein the voltage generator is further configured to:
generate a feedback voltage based on the pump voltage and a reference voltage.

9. The memory device of claim 8, wherein the voltage generator further includes a pump logic circuit, the pump logic circuit configured to:
receive the pump clock signal and the feedback voltage,
generate the control signal based on the feedback voltage, and
output the control signal to the multi-stage charge pump circuit.

10. The memory device of claim 7, wherein
in response to the counted number of cycles of the pump clock signal being equal to the data value of the reference count signal, the stage controller is further configured to output the counted number of cycles of the pump clock signal as the stage signal.

11. The memory device of claim 7, wherein the voltage generator is further configured to:
generate a first bias voltage and a second bias voltage based on the external power supply voltage, the first bias voltage having a level based on a level of the external power supply voltage.

12. The memory device of claim 11, wherein the voltage generator is further configured to:
output an auxiliary current based on a reference voltage and the external power supply voltage.

13. The memory device of claim 7, further comprising:
a row decoder configured to,
receive a row address signal associated with a read operation from the control logic circuit, the row address signal indicating a first cell string, among the plurality of cell strings,
provide the row voltage to the memory cell array based on the row address signal, and
perform a pre-charge operation corresponding to the read operation on the first cell string, the pre-charge operation including providing a pre-pulse voltage to the plurality of string select lines, the plurality of word lines, and the plurality of ground select lines connected to the first cell string based on the row address signal.

14. A storage device comprising:
at least one memory device including a memory cell array, the memory cell array including a plurality of cell strings, the at least one memory device configured to perform a read operation in response to a read signal;
a power circuit configured to supply an external power supply voltage to the memory device using a voltage received through an interface;
a voltage generator configured to output a pump clock signal, the outputting of the pump clock signal including setting a frequency of the pump clock signal based on a level of the external power supply voltage;
a stage controller configured to,
count a number of cycles of the pump clock signal, and
output a stage signal based on a data value of a reference count signal and the counted number of cycles of the pump clock signal;
a multi-stage charge pump circuit configured to,
determine one or more enable time periods based on the stage signal and a magnitude of the external power supply voltage, and
perform a pump operation based on a control signal and the determined one or more enable time periods; and
a word line voltage generator configured to output a word line voltage based on a pump voltage.

15. The storage device of claim 14, wherein the voltage generator is further configured to:
generate a feedback voltage based on the pump voltage and a reference voltage.

16. The storage device of claim 15, wherein the voltage generator further includes a pump logic circuit, the pump logic circuit configured to:
receive the pump clock signal and the feedback voltage,
generate the control signal based on the feedback voltage, and
output the control signal to the multi-stage charge pump circuit.

17. The storage device of claim 14, wherein
in response to the counted number of cycles of the pump clock signal being equal to the data value of the reference count signal, the stage controller is further configured to output the counted number of cycles of the pump clock signal as the stage signal.

18. The storage device of claim 14, wherein the voltage generator is further configured to:
generate a first bias voltage and a second bias voltage based on the external power supply voltage, the first bias voltage having a level based on a level of the external power supply voltage.

19. The storage device of claim 18, wherein the voltage generator is further configured to:
output an auxiliary current based on a reference voltage and the external power supply voltage.

20. The storage device of claim 14, further comprising:
a control logic circuit configured to control a row voltage supplied to a plurality of string select lines, a plurality of word lines, and a plurality of ground select lines; and
a row decoder configured to,
receive a row address signal associated with the read operation from the control logic circuit, the row address signal indicating a first cell string, among the plurality of cell strings,
provide the row voltage to the memory cell array based on the row address signal, and
perform a pre-charge operation on the first cell string, the pre-charge operation including providing a pre-pulse voltage to the plurality of string select lines, the plurality of word lines, and the plurality of ground select lines connected to the first cell string based on the row address signal.
